(19) United States
(12) Patent Application Publication
(10) Pub. No.: US 2026/0090458 A1
(43) Pub. Date: Mar. 26, 2026

(54) PRESSING METHOD AND PRESSING DEVICE

(71) Applicant: ALL RING TECH CO., LTD., KAOHSIUNG CITY (TW)

(72) Inventors: An-Tien WANG, KAOHSIUNG CITY (TW); Tai-Hung LIU, KAOHSIUNG CITY (TW); Chun-Hung TSAI, KAOHSIUNG CITY (TW)

(21) Appl. No.: 19/267,664

(22) Filed: Jul. 14, 2025

(30) Foreign Application Priority Data
Sep. 25, 2024 (TW) 113136503

(51) Int. Cl. H01L 21/48; B30B 1/18; B30B 1/34

(52) U.S. Cl. CPC H10W 76/01; B30B 1/18; B30B 1/34

(57) ABSTRACT

The present invention provides a pressing method and a pressing device. The method includes: providing an object to be pressed that is provided with pressing sections on an upper surface; providing a lower pressing die that is provided with a support seat for holding the object to be pressed; providing an upper pressing die that can be driven to move up and down relative to the lower pressing die and is provided with a driving mechanism and a pressing block mechanism that can be driven by the driving mechanism, and the pressing block mechanism is provided with independent and separated pressing block modules; and when the object to be pressed is pressed, the pressing block mechanism of the upper pressing die presses the upper surface of the object to be pressed, and the pressing block modules respectively apply pressure to the pressing sections of the object to be pressed.

### CROSS-REFERENCE TO RELATED APPLICATIONS

This application claims priority to Taiwan Application Serial Number 113136503, filed Sep. 25, 2024, which is herein incorporated by reference in its entirety.

### BACKGROUND

### Field of Invention

The present invention relates to a pressing method and a pressing device, and more particularly, to a pressing method and a pressing device for pressing an integrated circuit element covered by a lid.

### Description of Related Art

In a typical chip packaging process, there is often a need to cover an integrated circuit (IC) element with a lid. The integrated circuit element is usually formed by disposing at least one die or chip on a substrate. The lid is usually made of a metal material and has a heat dissipation function, so the lid is also referred as a heat dissipation lid or a heat sink. In the chip packaging process, a periphery of the substrate is coated with a liquid thermosetting adhesive, and a thermal interface material (TIM), such as a thermal interface material film (Film TIM), a metal thermal interface material (Metal TIM) or a liquid metal thermal interface material (Liquid Metal TIM), is applied on a top of the die or the chip. Then, the lid is placed on the integrated circuit, such that a center of the lid is against the thermal interface material and a lower edge of the lid is against the liquid thermosetting adhesive. After the lid is placed to cover the integrated circuit, the lid and the integrated circuit element are pressed and combined by an upper pressing die and a lower pressing die of a pressing device. The lower pressing die is provided with a horizontal supporting surface that can support the substrate. The upper pressing die is provided with a horizontal pressing surface that can press the lid. The upper pressing die can be driven to lower and press the lid to perform a pressing operation.

As technology advances, structures of the integrated circuit elements have become more and more complex. Electronic components of different shapes and sizes, such as dies, chips, optical communication components, or passive components, need to be stacked or arranged in different combinations on the substrate, so the shape of the lid will also have different height differences to match the electronic components. The prior art, which uses a horizontal pressing contact surface to press the lid, can only apply pressure to the highest area of the lid and cannot simultaneously apply pressure to the other lower areas of the lid. The lid is flexible, such that when the highest area of the lid is under pressure, portions with different heights will be subjected to different pressures, which may have different effects on the packaged objects under the lid. The portions with the different heights will be subjected to the different pressures, and the prior art does not provide any solution for determining the magnitude of the load applied on the portions, which shows that the prior art still needs to be improved.

### SUMMARY

Therefore, one objective of the present invention is to provide a pressing method that can solve at least one disadvantage of the prior art.

Another objective of the present invention is to provide a pressing device that can solve at least one disadvantage of the prior art.

Still another objective of the present invention is to provide a pressing device for performing the aforementioned pressing method.

The pressing method according to the objective of the present invention includes: providing an object to be pressed, in which the object to be pressed is provided with plural pressing sections on an upper surface of the object to be pressed; providing a lower pressing die, in which the lower pressing die is provided with a support seat for holding the object to be pressed; providing an upper pressing die, in which the upper pressing die can be driven to move up and down relative to the lower pressing die, the upper pressing die is provided with a driving mechanism and a pressing block mechanism that can be driven by the driving mechanism, and the pressing block mechanism is provided with plural pressing block modules that are independent and separated from each other; and when the object to be pressed is pressed, the pressing block mechanism of the upper pressing die presses the upper surface of the object to be pressed, and the pressing block modules respectively apply pressure to the pressing sections of the object to be pressed.

The pressing device according to another objective of the present invention includes: a lower pressing die provided with a support seat for holding an object to be pressed; an upper pressing die capable of being driven to move up and down relative to the lower pressing die, in which the upper pressing die is provided with a driving mechanism and a pressing block mechanism that can be driven by the driving mechanism, and the pressing block mechanism is provided with plural pressing block modules that are independent and separated from each other; and a lifting mechanism capable of driving the upper pressing die to move up and down relative to the lower pressing die to make the pressing block mechanism press against the object to be pressed or move away from the object to be pressed.

The pressing device according to still another objective of the present invention can be used to perform the pressing method as described above.

In the pressing method and the pressing device of the embodiment of the present invention, the pressing block mechanism of the upper pressing die is provided with plural independently and separately pressing block modules. Therefore, when the driving mechanism drives the pressing block mechanism to press the object W to be pressed, the pressing block modules of the pressing block mechanism of the upper pressing die respectively apply pressure to the pressing sections of the object to be pressed and press the upper surface of the object to be pressed, such that the different pressing sections can bear independent force respectively to meet the force requirements of the different pressing sections.

### BRIEF DESCRIPTION OF THE DRAWINGS

FIG. 1 is a three-dimensional diagram illustrating an object to be pressed according to an embodiment of the present invention.

FIG. 2 is a three-dimensional exploded diagram illustrating that the object to be pressed is an integrated circuit element covered with a lid.

FIG. 3 is a cross-sectional view illustrating an A-A section of FIG. 1.

FIG. 4 is a cross-sectional view illustrating a B-B section of FIG. 1.

FIG. 5 is a three-dimensional diagram illustrating a pressing device according to an embodiment of the present invention.

FIG. 6 is a schematic diagram illustrating a corresponding relationship between an upper pressing die of the pressing device and the object to be pressed.

FIG. 7 is a three-dimensional exploded diagram illustrating a first pressing block module, a second pressing block module, and a third pressing block module of the upper pressing die.

FIG. 8 is a partial cross-sectional view corresponding to the third pressing block module, illustrating the upper pressing die of the pressing device.

FIG. 9 is a three-dimensional exploded diagram illustrating a structure of an upper surface of each pressing block assembly in the upper pressing die.

FIG. 10 is a side view illustrating the object to be pressed being placed in the pressing device.

FIG. 11 is a side view illustrating the upper pressing die being driven to descend.

FIG. 12 is a partial cross-sectional view taken along the A-A section line in FIG. 1, illustrating the upper pressing die performing a pressing operation on the object to be pressed.

### DETAILED DESCRIPTION

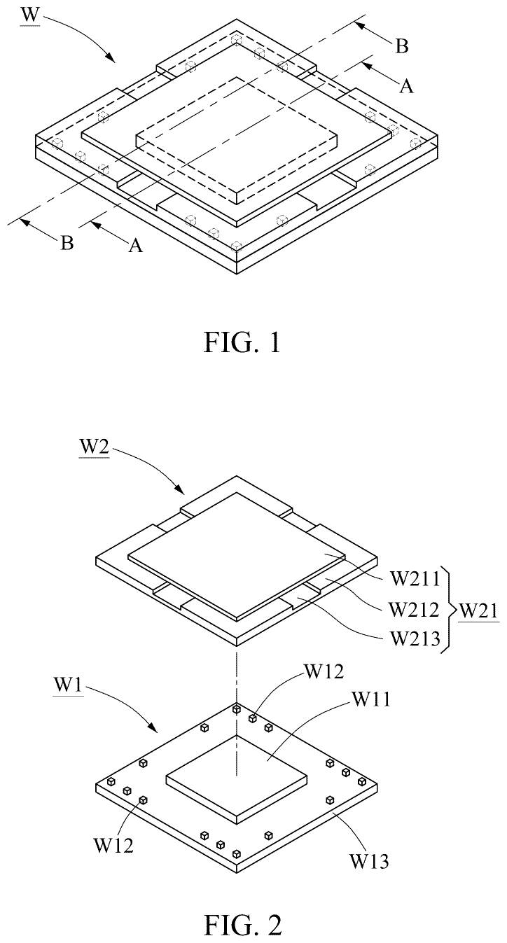

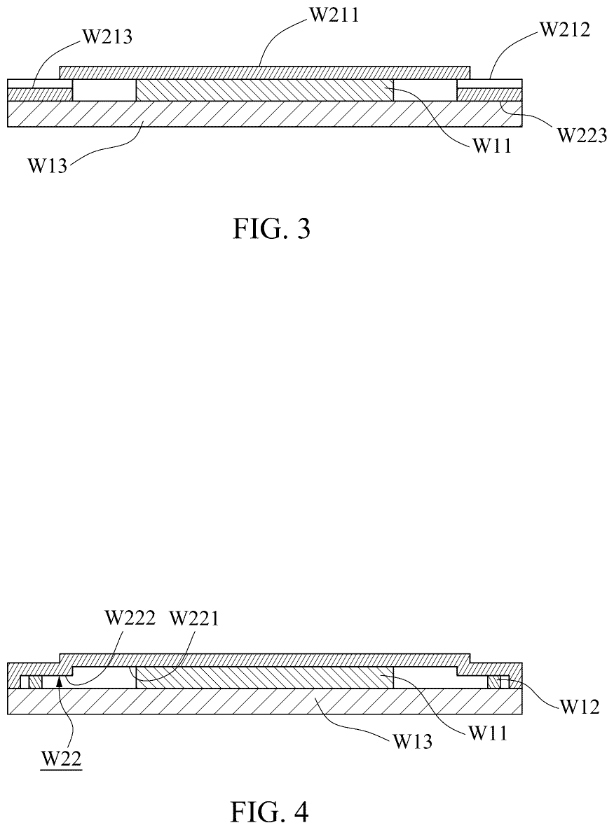

Referring to FIG. 1, FIG. 2, FIG. 3, and FIG. 4, a pressing method and a pressing device according to an embodiment of the present invention are suitable for pressing an object W to be pressed as shown in the figures. The object W to be pressed is formed by covering an upper side of an integrated circuit element W1 with a lid W2. The integrated circuit element W1 includes a first electronic component W11 and plural second electronic components W12 on an upper side of a substrate W13. An upper surface W21 of the lid W2 is provided with plural pressing sections of different heights, which include a first pressing section W211, a second pressing section W212, and a third pressing section W213, in accordance with heights of the first electronic component W11, the second electronic components W12, and the substrate W13. A lower surface W22 of the lid W2 corresponding to the integrated circuit element W1 is provided with a first abutting surface W221, a second abutting surface W222, and a third abutting surface W223 of different heights in accordance with the heights of the first electronic component W11, the second electronic components W12, and the substrate W13 respectively. In the embodiment of the present invention, the first pressing section W211, the second pressing section W212, and the third pressing section W213 are classified by height, so areas of the same height in the upper surface W21 are classified into the same pressing section. Therefore, as shown in FIG. 2, the first pressing section W211 is a slightly rectangular area located in a middle of the upper surface W21, the second pressing section W212 is four slightly L-shaped areas located at four corners of the upper surface W21, and the third pressing section W213 is four slightly rectangular areas located in middles of outer edges of the periphery of the first pressing section W211. The first abutting surface W221, the second abutting surface W222, and the third abutting surface W223 are also classified by height, so areas of the same height in the lower surface W22 are classified into the same type of abutting surface. The first abutting surface W221 is located in an area in a middle of the lower surface W22, the second abutting surface W222 is located in four areas at four corners of the lower surface W22, and the third abutting surface W223 is located in four areas in middles of outer edges of the periphery of the lower surface W22. In other words, the first abutting surface W221, the second abutting surface W222, and the third abutting surface W223 are respectively corresponding to and below the first pressing section W211, the second pressing section W212, and the third pressing section W213. The first electronic component W11 may be an electronic component, such as a chip or a die that is mainly for data calculation, and the second electronic components W12 may be electronic components, such as silicon photonics or other optical communication components that are mainly for data transmission. The first electronic component W11 and the second electronic components W12 may be fixed on the substrate W13 by an adhesive. The portion of the first electronic component W11 corresponding to the first abutting surface W221 may be applied with a thermal interface material (not shown). The portions of the second electronic components W12 corresponding to the second abutting surface W222 may be applied with a thermal interface material (not shown). The periphery of the substrate W13 may be coated with a liquid adhesive (not shown), such that the lid W2 is attached and fixed thereon through the third abutting surface W223, and the first electronic component W11 and the second electronic components W12 of the integrated circuit element W1 are encapsulated between the substrate W13 and the lid W2, and are surrounded by the liquid adhesive on the periphery of the substrate W13. Now, the first abutting surface W221 of the lid W2 abuts against the first electronic component W11, and the second abutting surface W222 of the lid W2 abuts against the second electronic components W12.

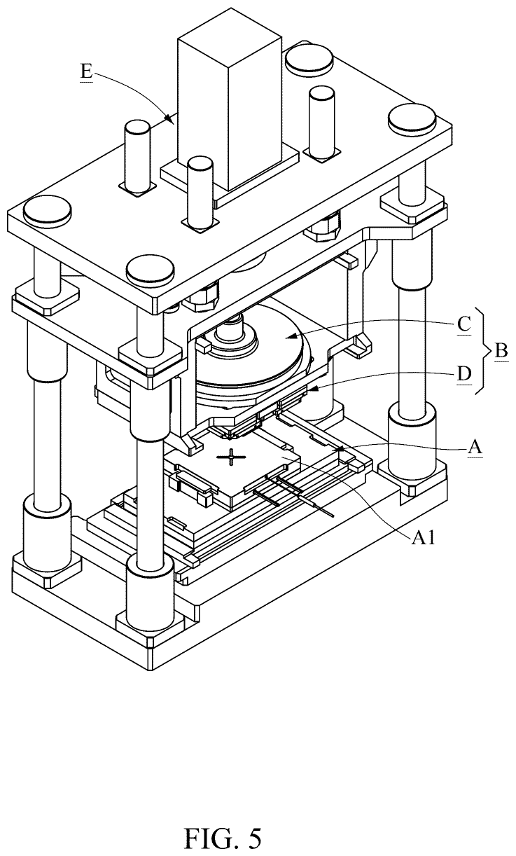

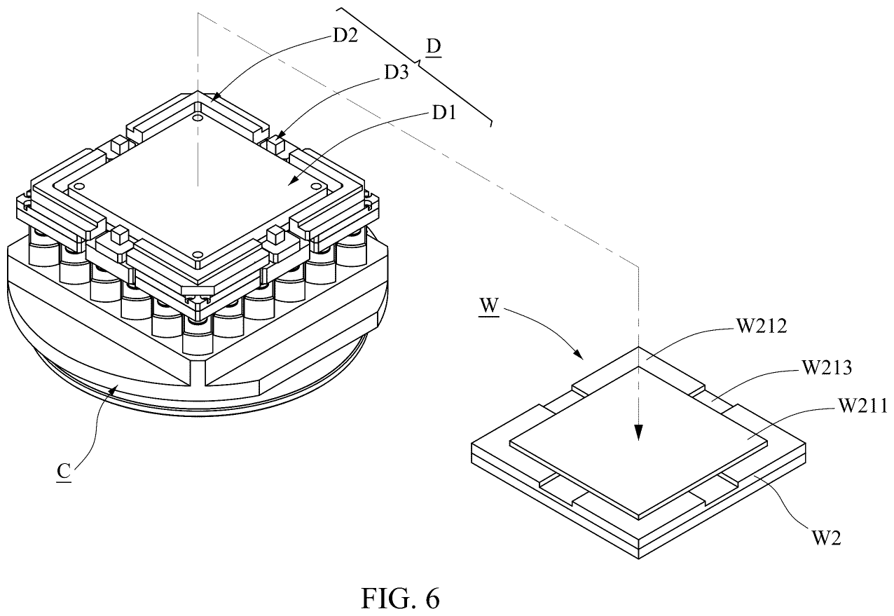

Referring to FIG. 5 and FIG. 6, the pressing method of the embodiment of the present invention can be illustrated by using the process performed by the pressing device as shown in the figures. The pressing device includes: a lower pressing die A that is provided with a support seat A1 for holding the object W to be pressed; an upper pressing die B that is provided with a driving mechanism C and a pressing block mechanism D located below the driving mechanism C and driven by the driving mechanism C; and a lifting mechanism E that can drive the upper pressing die B to move up and down relative to the lower pressing die A to make the pressing block mechanism D press against the lid W2 or move away from the lid W2. The pressing block mechanism D is provided with plural independent and separate pressing block modules, including: a first pressing block module D1 corresponding to the first pressing section W211, a second pressing block module D2 corresponding to the second pressing section W212, and a third pressing block module D3 corresponding to the third pressing section W213.

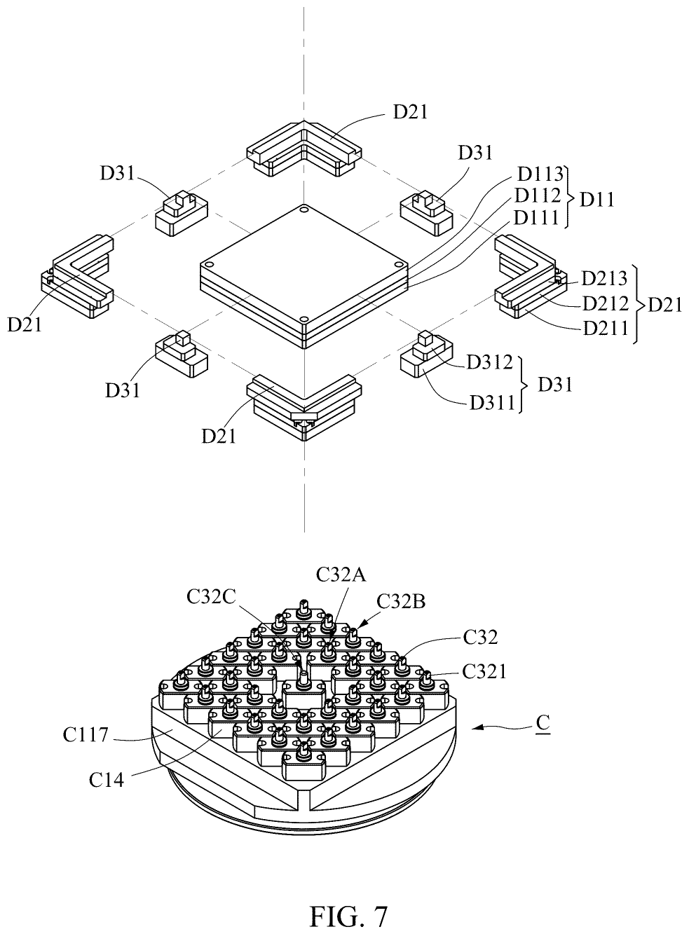

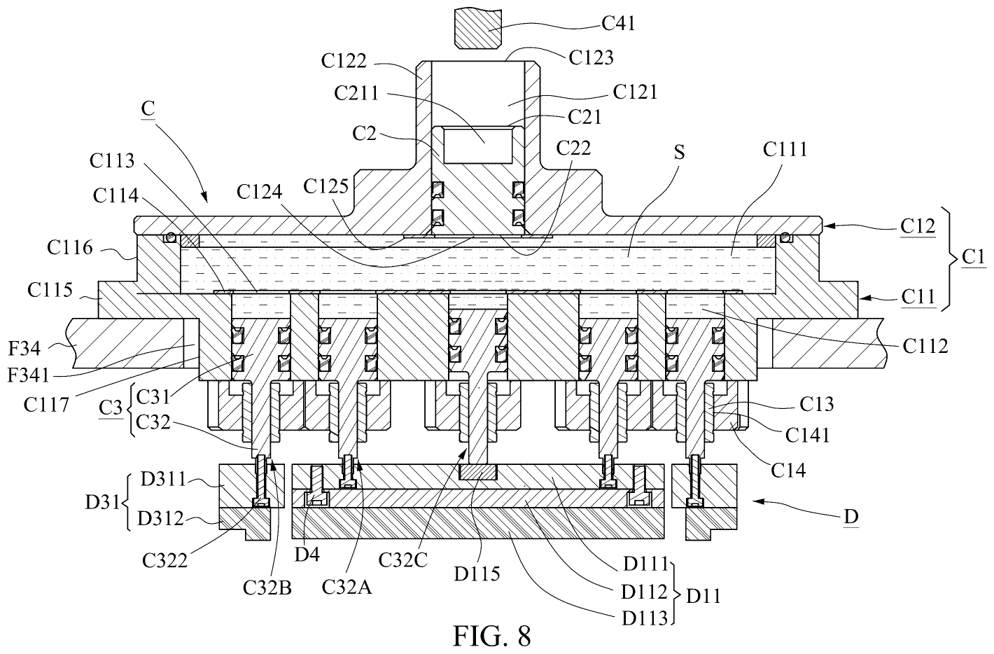

Referring to FIG. 6 to FIG. 8, in the embodiment of the present invention, the first pressing block module D1, the second pressing block module D2, and the third pressing block module D3 are classified according to the corresponding pressing sections. Therefore, as shown in FIG. 7, the first pressing block module D1 is a first pressing block assembly D11 located in a middle of the pressing block mechanism D and is slightly rectangular, the second pressing block module D2 is composed of four second pressing block assemblies D21 in a shape of a symbol “ [symbol] ” and located at four corners of the pressing block mechanism D, and the third pressing block module D3 is composed of four third pressing block assemblies D31 that are slightly rectangular and located in middles of outer edges of the first pressing block assembly D11 in the pressing block mechanism D. The first pressing block module D1, the second pressing block module D2 and the third pressing block module D3 are assemblies that are kept spaced, separated from each other, and independent of each other. Each of the pressing block assemblies in each of the pressing block modules is also independent and separate. The first pressing block assembly D11 is a structure consisting of three layers. The top layer is a fixing member D111 made of a metal material, such as an aluminum alloy. The middle layer is a fine-tuning member D112 made of a metal material, such as iron. The bottom layer is a pressing member D113 made of a non-metallic material, such as engineering plastic, and is fixed under the fine-tuning member D112 and has a lower surface for pressing against and contacting the object to be pressed. The second pressing block assembly D21 is a structure consisting of three layers. The top layer is a fixing member D211 made of a metal material, such as an aluminum alloy. The middle layer is a fine-tuning member D212 made of a metal material, such as iron. The bottom layer is a pressing member D213 made of a non-metallic material, such as engineering plastics, and is fixed under the fine-tuning member D212 and has a lower surface for pressing against and contacting the object to be pressed. The third pressing block assembly D31 is a structure consisting of two layers. The upper layer is a fixing member D311 made of a metal material, such as an aluminum alloy. The lower layer is made of a non-metal material, such as engineering plastics and is a pressing member D312 in a T shape, and is fixed under the fixing member D311 and has a lower surface for pressing against and contacting the object to be pressed. In addition, the fine-tuning member D112 of the middle layer of the first pressing block assembly D11 is screwed under the fixing member D111 by plural screws D4 (FIG. 8), and a level of a lower surface of the fine-tuning member D112 is adjusted by screwing the screws D4. The fine-tuning member D212 of the middle layer of the second pressing block assembly D21 is screwed under the fixing member D211 by plural screws D5 (not shown in the figure, and the screwing method of which is similar to that of the screws D4), and a level of a lower surface of the fine-tuning member D212 can be adjusted by screwing the screws D5.

Referring to FIG. 8, the driving mechanism C includes a main body C1 having a chamber C111 that can accommodate a fluid S, a piston C2 that can change the pressure of the fluid S in the chamber C111 via displacement, and plural plungers C3 that can be simultaneously driven by the pressure of the fluid S in the chamber C111 to move up and down. For example, the fluid S is liquid or hydraulic oil. The main body C1 includes a seat body C11 and a cover C12, and the chamber C111 is a space enclosed by the seat body C11 and the cover C12. The main body C1 has a piston channel C121, which is located in a shaft seat C122 protruding from a center of the cover C12 and is arranged vertically axially, for the piston C2 to move therein. The piston C2 is not connected to any components at the top and the bottom, and can freely move up and down in the piston channel C121 when subjected to an external force. The piston channel C121 is connected to the chamber C111, such that the pressure of the fluid S in the chamber C111 can be changed according to the displacement of the piston C2. The height of the piston C2 is smaller than the length of the piston channel C121. The piston C2 has an upper end portion C21 and a lower end portion C22. The upper end portion C21 is provided with a push portion C211 in a groove-shape, and a lower end of a driving rod C41 is put into the push portion C211 to contact and push the push portion C211 to move the piston C2. An upper end of the piston channel C121 is an open port C123, and a lower end is blocked by a stopper C125 having a through hole C124. The fluid S in the chamber C111 communicates with the piston channel C121 via the through hole C124. The main body C1 is provided with plural plunger channels C112 in a bottom of the seat body C11 below the chamber C111 for the plungers C3 to move therein respectively, in which the plunger channels C112 are vertically arranged, spaced apart from each other, and parallel to each other. Each of the plunger channels C112 is blocked by a blocking member C114 having a through hole C113. The fluid S in the chamber C111 communicates with the plunger channels C112 via the through holes C113. The blocking member C114 is provided with plural through holes C113, and each of the through holes C113 corresponds to one of the plunger channels C112. The change of the pressure of the fluid S in the chamber C111 can link the up and down displacement of the plungers C3. Each of the plungers C3 includes a force-bearing portion C31 capable of bearing the pressure of the fluid S, and a pressing rod C32 extending downward and integrally from the force-bearing portion C31 and protruding from the seat body C11. The pressing block mechanism D can be directly pressed by the plungers C3 through the pressing rods C32. A cross-sectional diameter of the force-bearing portion C31 is greater and located at the top, and a rod diameter of the pressing rod C32 is smaller and located under the force-bearing portion C31. The seat body C11 is provided with the support seat C115 protruding from a periphery of the seat body C11. An upper seat body C116 formed with the chamber C111 inside is formed on the upper side of the seat body C115 and is circular with a larger outer diameter. A lower seat body C117 formed with the plunger channels C112 inside is formed on the lower side of the seat body C115, and is rectangular and has a narrower outer diameter between the parallel corresponding sides. The main body C1 is placed in a hollow space F341 of a lower slide seat F34 through the lower seat body C117, and the support seat C115 is placed and fixed on an upper edge of the lower slide seat F34 on a periphery of the hollow space F341. The main body C1 includes plural bushings C13 respectively corresponding to the plungers C3, and plural sleeves C14 for fixing the bushings C13 under the seat body C11. A lower opening of the plunger channel C112 is closed by the sleeve C14. The sleeve C14 has an axial hole C141, in which the bushing C13 is disposed, and the pressing rod C32 can pass through the bushing C13 and be guided by the bushing C13. An upper end edge of the bushing C13 limits the bottom dead point of the downward movement of the plunger C3.

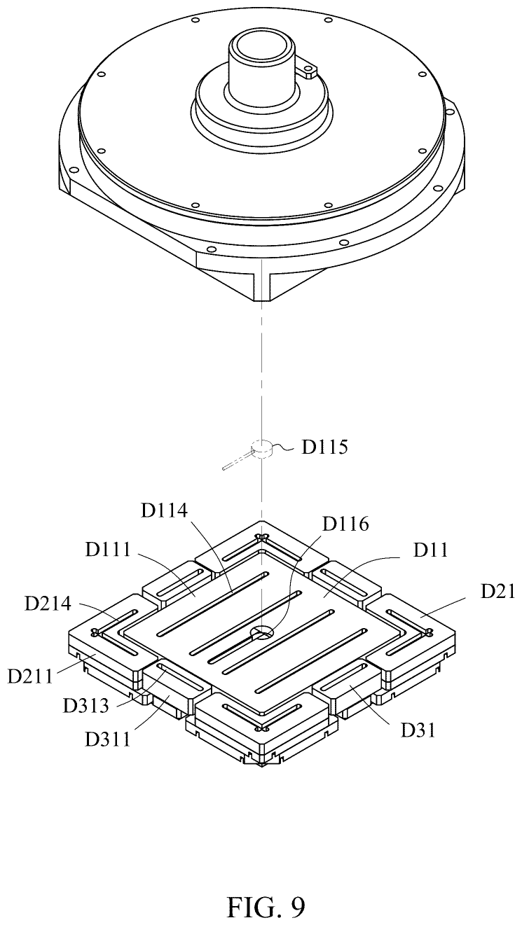

Referring to FIG. 7, FIG. 8, and FIG. 9, each of the sleeves C14 is slightly rectangular (with two slightly curved sides) and is arranged at an angle of 45 degrees relative to the rectangular lower seat body C117. The pressing rods C32 protruding downward from the bottom of the sleeves C14 and the sleeves C14 are arranged in three groups with the same center on a rectangular lower surface of the lower seat body C117, including a first group C32A and a second group C32B arranged in two separated rectangular frames that are arranged in a shape of a symbol “ [symbol] ”, and a third group C32C located in a center of the shape of the symbol“ [symbol] ”. The pressing rods C32 in the first group C32A are arranged in a smaller one of the rectangular frames and are used to connect and fix the first pressing block assembly D11, the pressing rods C32 in the second group C32B are arranged in a larger one of the rectangular frames and are used to connect and fix the second pressing block assemblies D21 and the third pressing block assemblies D31, and the third group C32C has only one independent pressing rod C32. A lower end of each pressing rod C32 is provided with a positioning portion C321, and the positioning portion C321 is formed by cutting off two sides of the round bar, such that the positioning portion C321 has two sides parallel to each other. The first pressing block assembly D11, the second pressing block assemblies D21, and the third pressing block assemblies D31 of the pressing block mechanism D are respectively provided with a positioning groove D114, a positioning groove D214, and a positioning groove D313, which are straight long groove-shaped and respectively recessed in the fixing member D111, the fixing member D211, and the fixing member D311, such that the positioning portion C321 at the lower end of each pressing rod C32 can embed. In addition, connecting members C322 such as screws are respectively screwed upward from the fixing member D111, the fixing member D211, and the fixing member D311 of the pressing block mechanism D to the positioning portions C321 of the pressing rods C32 to connect and prevent the first pressing block assembly D11, the second pressing block assembly D21, and the third pressing block assembly D31 from sliding and rotating. A load measuring unit D115 is disposed between one of the plungers C3 and a corresponding one of the pressing block assemblies of the pressing block mechanism D. The pressing block mechanism D can be pressed indirectly by the plunger C3 with the pressing rod C32 via the load measuring unit D115. For example, in the arranging of the load measuring unit D115, a carrying area D116 is recessed in a center of the fixing member D111 of the first pressing block assembly D11, and the carrying area D116 is used to accommodate the load measuring unit D115. The pressing rod C32 of the plunger C3 of the third group C32C independently arranged in the center of the shape of the symbol “ [symbol] ” just correspondingly presses the load measuring unit D115, such that when the fluid S is subjected to the piston C2 and changes the volume of the chamber C111 to apply force to the plunger C3, the plunger C3 is driven to press against the load measuring unit D115 by the force of the fluid S. Corresponding to the load measuring unit D115, the positioning portion C321 at the lower end of the pressing rod C32 can omit a corresponding screw hole structure for being screwed by a screw or omit cutting off both sides of the round rod section to form a structure with two parallel sides, and only the bottom of the pressing rod C32 is used to abut against the load measuring unit D115.

In the embodiment of the present invention, the fluid S is hydraulic oil. Horizontal cross-sections of the plunger channels C112 are circular and have the same horizontal cross-sectional area, and horizontal cross-sections of the force-bearing portions C31 of the plungers C3 are circular and have the same horizontal cross-sectional area, such that the plungers C3 are subjected to the same pressure applied by the fluid S. In other possible embodiment, the horizontal cross-sectional areas of the force-bearing portions C31 of several ones of the plungers C3 may be changed according to the requirements, such that the different plungers C3 bear different pressures. Therefore, in the present embodiment, the horizontal cross-sectional areas of the force-bearing portions C31 of the plungers C3 are the same, such that only through the load measuring unit D115 and the corresponding plunger C3 of the third group C32C independently arranged in the center of the shape of a symbol “ [symbol] ”, the force borne by each of the force-bearing portions C31 of the same horizontal cross-sectional area and the force applied by the pressure rods C32 to the pressing block mechanism D can be measured. When the horizontal cross-sectional areas of the force-bearing portion C31 of several ones of the plungers C3 are changed in the other embodiments, the number of the load measuring units D115 can be increased, in which the load measuring units D115 are arranged at the positions corresponding to the force-bearing portions C31 of the plungers C3 with different horizontal cross-sectional areas.

Referring to FIG. 6 to FIG. 9, the pressing block mechanism D is disposed at one end of the plunger C3. In addition to the first pressing block module D1, the second pressing block module D2, and the third pressing block module D3 being connected to the corresponding pressing rods C32 of the plungers C3, each positioning groove D114, positioning groove D214, positioning groove D313 is correspondingly used for the positioning portions C321 at the lower ends of the pressing rods C32 to be embedded. The preferred configuration is to be embedded with at least two positioning portions C321 at the lower ends of the pressing rods C32. The horizontal cross-sections of the plunger channel C112 and the force-bearing portion C31 of the plunges C3 are circular, such that the plunger C3 may pivot due to the force-bearing portion C31 in the plunger channels C112. In order to prevent the pivoting of the plungers C3 from causing the first pressing block module D1, the second pressing block module D2, and the third pressing block module D3 to deviate in angle, each first pressing block assembly D11, second pressing block assembly D21, and third pressing block assembly D31 is connected to at least two positioning portions C321 of the pressing rods C32 of the plungers C3, which not only provides better support for the first pressing block assembly D11, the second pressing block assembly D21, and the third pressing block assembly D31, but also limits the pivoting of the plunger C3.

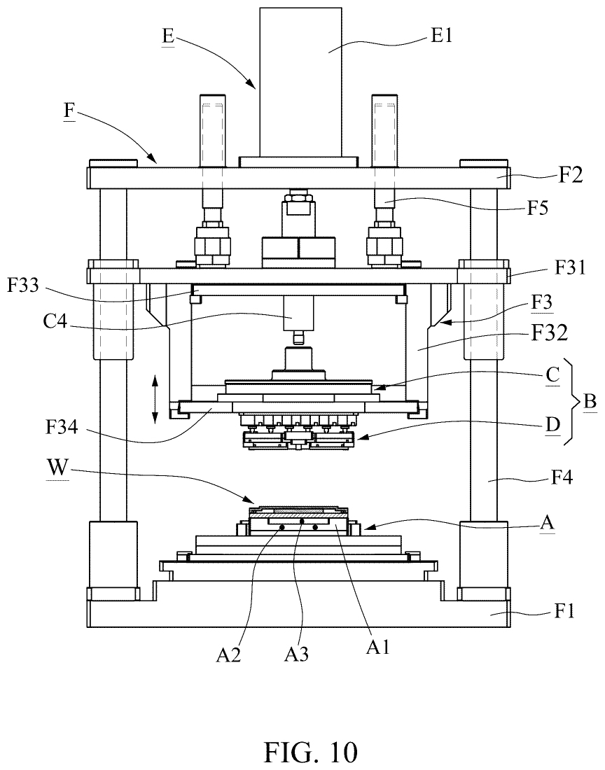

Referring to FIG. 8 and FIG. 10, the pressing device includes a seat frame F provided with a base seat F1 and a top seat F2, which are parallel to each other and are kept at a fixed distance. Plural support rods F4 are disposed between the base seat F1 and the top seat F2 to keep the distance between the base seat F1 and the top seat F2. The seat frame F is provided with a lifting frame F3 pivotally mounted on the support rods F4. The lifting frame F3 is provided with plural guide rods F5, in which one end of each guide rod F5 is fixed to the lifting frame F3 and the other end is pivotally mounted to the top seat F2. The lifting mechanism E is provided with a lifting driver E1 such as a pneumatic cylinder on the top seat F2, and the lifting driver E1 can drive the lifting frame F3 to move up and down. The lifting frame F3 is provided with a carrying seat F31 fixed to one end of each guide rod F5. Two side seats F32 are vertically disposed on two sides separated by a gap under the carrying seat F31 respectively. An upper slide seat F33 disposed horizontally at the top and a lower slide seat F34 disposed horizontally at the bottom are provided between the two side seats F32 at a distance from each other. The upper slide seat F33 and the lower slide seat F34 can be horizontally moved and removed from the two side seats F32. The upper pressing die B is disposed on the lifting frame F3 and moves with the lifting frame F3. The upper pressing die B is disposed on the lower slide seat F34, and the lower pressing die A is disposed on the base seat F1 and is located below the upper pressing die B. The lower pressing die A is provided with a heater A2 and a temperature sensor A3 in the support seat A1. The driving mechanism C is provided with a piston driver C4, such as a pneumatic cylinder, located outside the main body C1, one end of the piston driver C4 is fixed on the bottom of the upper slide seat F33, and the other end of the piston driver C4 is provided with a driving rod C41 extending downward. The driving rod C41 is separated from the piston C2 and maintains a certain distance from the piston C2, but when the driving rod C41 is driven downward, it can push the piston C2 to change the pressure of the fluid S in the chamber C111. An upper end of the shaft seat C122 at the upper end of the piston channel C121 and a lower end of the driving rod C41 are generally kept separated by a distance.

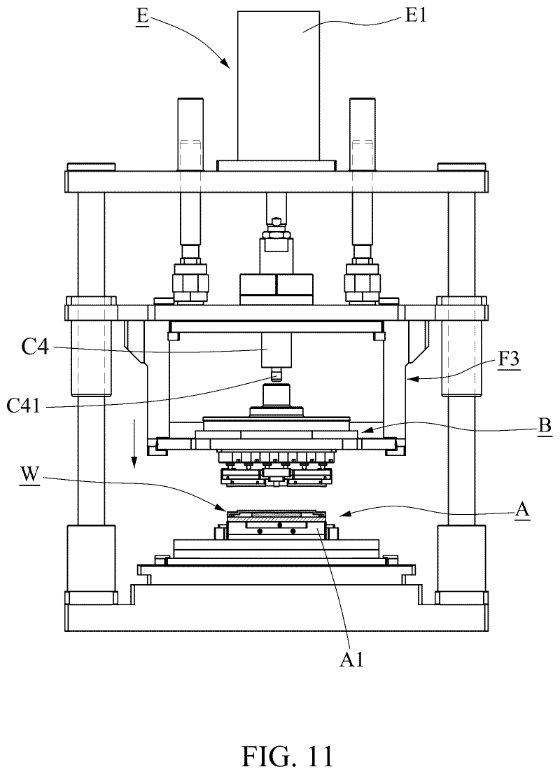

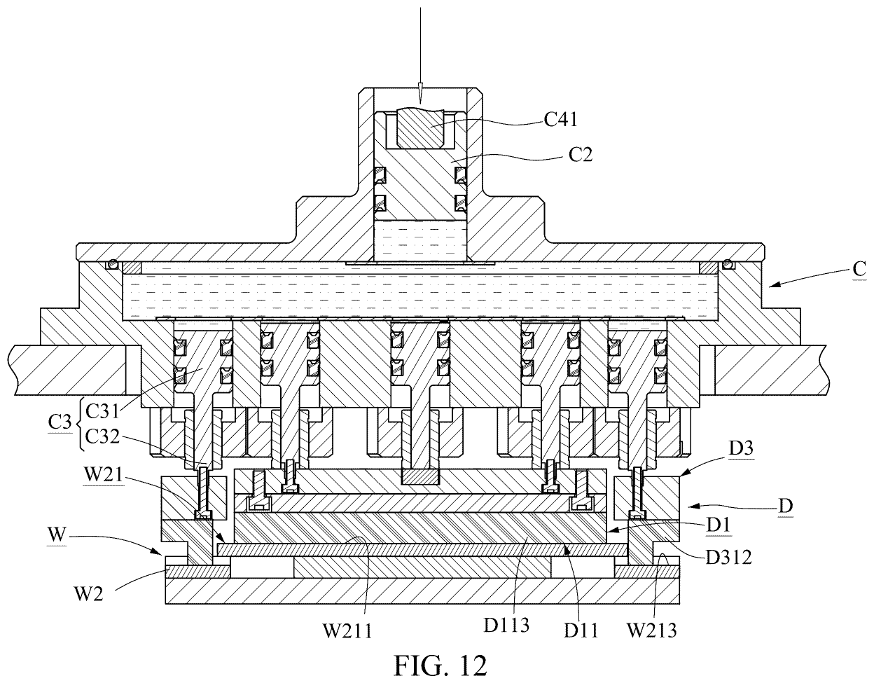

Referring to FIG. 6, FIG. 7, FIG. 11, and FIG. 12, when the embodiment of the present invention is implemented to press the object W to be pressed, after the object W to be pressed is placed on the support base A1 of the lower pressing die A, the lifting driver E1 of the lifting mechanism E drives the lifting frame F3 to move the upper pressing die B downward toward the lower pressing die A to firstly lower the upper pressing die B until the pressing block mechanism D presses against the upper surface W21 of the lid W2 of the object W to be pressed. The object W to be pressed is provided with plural pressing sections with different heights, such that the upper pressing mold B descends until the bottommost pressing member D113 of the first pressing block assembly D11 of the first pressing block module D1 presses against the first pressing section W211 of the lid W2, the bottommost pressing members D213 of the four second pressing block assemblies D21 of the second pressing block module D2 press against the second pressing sections W212 of the lid W2, and the four third pressing block assemblies D31 of the third pressing block module D3 press against the third pressing sections W213 of the lid W2. At this point, the first pressing block module D1, the second pressing block module D2, and the third pressing block module D3 are located at different heights, such that the pressing block mechanism D applies an upward pressure to the plungers C3, and drives the corresponding plungers C3 to move upward. In the case that the volume of the fluid S does not change, the fluid S pushes the piston C2 to move upward. After the upper pressing die B descends to the pressing block mechanism D and presses against the lid W2 of the object W to be pressed, the driving rod C41 of the piston driver C4 of the driving mechanism C pushes the piston C2 downward (as shown in FIG. 11) to act on the fluid S in the chamber C111. In the case that the volume of the fluid S does not change, a reverse downward pressure is indirectly applied to the plungers C3 through the fluid S, such that the plungers C3 applies pressure to the object W to be pressed. The plungers C3 simultaneously bear the pressure of the fluid S and are pushed downward, such that the driving mechanism C drives the first pressing block module D1, the second pressing block module D2, and the third pressing block module D3 of the pressing block mechanism D to apply the same pressure to the first pressing section W211, the second pressing section W212, and the third pressing section W213 of the lid W2 respectively at the same time. The pressure is detected by the pressing rod C32 of the third group C32C independently arranged in the center of the shape of a symbol “ [symbol] ” correspondingly contacting the load measuring unit D115 downward. Referring to FIG. 2 simultaneously, at this point, the first abutting surface W221 correspondingly located below the first pressing section W211 abuts against the first electronic component W11 to make the first electronic component W11 abut against the substrate W13, the second abutting surface W222 correspondingly located below the second pressing section W212 abuts against the second electronic components W12 to make the second electronic components W12 abut against the substrate W13, and the third abutting surface W223 correspondingly located below the third pressing section W213 abuts against the substrate W13, such that the lid W2 can be pressurized and combined with the integrated circuit element W1.

In the pressing method and the pressing device of the embodiment of the present invention, the pressing block mechanism D of the upper pressing die B is provided with plural independently and separately pressing block modules. Therefore, when the driving mechanism C drives the pressing block mechanism D to press the object W to be pressed, the pressing block modules of the pressing block mechanism of the upper pressing die respectively apply pressure to the pressing sections of the object W to be pressed and press the upper surface of the object W to be pressed, such that the different pressing sections can bear independent force respectively to meet the force requirements of the different pressing sections.

However, what is described above is merely embodiments of the present invention and should not be used to limit the implementation scope of the present invention. All simple equivalent changes and modifications made in accordance with the claims and the specification of the present invention are within the scope of the present invention.

What is claimed is:

1. A pressing method, comprising:
providing an object to be pressed, wherein the object to be pressed is provided with a plurality of pressing sections on an upper surface of the object to be pressed;
providing a lower pressing die, wherein the lower pressing die is provided with a support seat for holding the object to be pressed;
providing an upper pressing die, wherein the upper pressing die can be driven to move up and down relative to the lower pressing die, the upper pressing die is provided with a driving mechanism and a pressing block mechanism that can be driven by the driving mechanism, and the pressing block mechanism is provided with a plurality of pressing block modules that are independent and separated from each other; and
when the object to be pressed is pressed, the pressing block mechanism of the upper pressing die presses the upper surface of the object to be pressed, and the pressing block modules respectively apply pressure to the pressing sections of the object to be pressed.

2. The pressing method of claim 1, wherein the object to be pressed comprises an integrated circuit element and a lid covering an upper side of the integrated circuit element, and an upper surface of the lid is provided with a plurality of pressing sections of different heights.

3. The pressing method of claim 2, wherein:
the integrated circuit element comprises a first electronic component and a plurality of second electronic components on an upper side of a substrate;
the upper surface of the lid is provided with the pressing sections, which comprise a first pressing section, a second pressing section, and a third pressing section, in accordance with the first electronic component, the second electronic components, and the substrate respectively; and
a lower surface of the lid corresponding to the integrated circuit element is provided with a first abutting surface, a second abutting surface, and a third abutting surface in accordance with the first electronic component, the second electronic components, and the substrate respectively.

4. The pressing method of claim 3, wherein:
the first pressing section, the second pressing section, and the third pressing section are classified by height, so areas of the same height in the upper surface are classified into the same pressing section; and
the first pressing section is a slightly rectangular area located in a middle of the upper surface, the second pressing section is four slightly L-shaped areas located at four corners of the upper surface, and the third pressing section is four slightly rectangular areas located in middles of outer edges of a periphery of the first pressing section.

5. The pressing method of claim 3, wherein:
the first abutting surface, the second abutting surface, and the third abutting surface are classified by height, so areas of the same height in the lower surface are classified into the same type of abutting surface;
the first abutting surface is located in an area in a middle of the lower surface, the second abutting surface is located in four areas at four corners of the lower surface, and the third abutting surface is located in four areas in middles of outer edges of a periphery of the lower surface; and
first abutting surface, the second abutting surface, and the third abutting surface are respectively corresponding to and below the first pressing section, the second pressing section, and the third pressing section.

6. The pressing method of claim 3, wherein:
the first electronic component is a chip or a die for data calculation, and the second electronic components are silicon photonics or optical communication components for data transmission;
the first electronic component and the second electronic components are fixed on the substrate by an adhesive;
a portion of the first electronic component corresponding to the first abutting surface is applied with a thermal interface material;
portions of the second electronic components corresponding to the second abutting surface is applied with the thermal interface material; and
a periphery of the substrate is coated with a liquid adhesive, such that the lid is attached and fixed thereon through the third abutting surface, and now, the first abutting surface of the lid abuts against the first electronic component, and the second abutting surface of the lid abuts against the second electronic components.

7. A pressing device, comprising:
a lower pressing die provided with a support seat for holding an object to be pressed;
an upper pressing die capable of being driven to move up and down relative to the lower pressing die, wherein the upper pressing die is provided with a driving mechanism and a pressing block mechanism that can be driven by the driving mechanism, and the pressing block mechanism is provided with a plurality of pressing block modules that are independent and separated from each other; and
a lifting mechanism capable of driving the upper pressing die to move up and down relative to the lower pressing die to make the pressing block mechanism press against the object to be pressed or move away from the object to be pressed.

8. The pressing device of claim 7, wherein:
the pressing block modules comprise a first pressing block module, a second pressing block module, and a third pressing block module; and
the first pressing block module is a first pressing block assembly located in a middle of the pressing block mechanism and is slightly rectangular, the second pressing block module is composed of four second pressing block assemblies in a shape of a symbol “ [symbol] ” and located at four corners of the pressing block mechanism, and the third pressing block module is composed of four third pressing block assemblies that are slightly rectangular and located in middles of outer edges of the first pressing block assembly in the pressing block mechanism.

9. The pressing device of claim 8, wherein the first pressing block assembly is a structure consisting of three layers, and wherein:
a top layer is a fixing member made of a metal material;
a middle layer is a fine-tuning member made of another metal material, the fine-tuning member is screwed under the fixing member by screws, and a level of a lower surface of the fine-tuning member is adjusted by screwing the screws; and
a lower layer is a pressing member made of a non-metal material, and is fixed under the fine-tuning member and has a lower surface for pressing against and contacting the object to be pressed.

10. The pressing device of claim 8, wherein each of the second pressing block assemblies is a structure consisting of three layers, and wherein:
a top layer is a fixing member made of a metal material;
a middle layer is a fine-tuning member made of another metal material, the fine-tuning member is screwed under the fixing member by screws, and a level of a lower surface of the fine-tuning member is adjusted by screwing the screws; and
a lower layer is a pressing member made of a non-metal material, and is fixed under the fine-tuning member and has a lower surface for pressing against and contacting the object to be pressed.

11. The pressing device of claim 8, wherein each of the third pressing block assemblies is a structure consisting of two layers, and wherein:
an upper layer is a fixing member made of a metal material; and
a lower layer is a pressing member made of a non-metal material, and is fixed under the fixing member and has a lower surface for pressing against and contacting the object to be pressed.

12. The pressing device of claim 7, wherein the upper pressing die comprises a driving mechanism that is provided with a plurality of plungers, each of the plungers comprises a force-bearing portion capable of bearing pressure of a fluid, and a pressing rod extending downward and integrally from the force-bearing portion, and the pressing block mechanism can be pressed by the plungers through the pressing rods.

13. The pressing device of claim 12, wherein:
the pressing rods are arranged in three groups with the same center, and the three groups comprises a first group and a second group arranged in two separated rectangular frames that are arranged in a shape of a symbol “ [symbol] ”, and a third group located in a center of the shape of the symbol “ [symbol] ”;
the pressing rods in the first group are arranged in a smaller one of the rectangular frames and are used to connect and fix a first pressing block assembly;
the pressing rods in the second group are arranged in a larger one of the rectangular frames and are used to connect and fix a second pressing block assemblies and a third pressing block assemblies; and
the third group has only independent one of the pressing rods.

14. The pressing device of claim 13, wherein a load measuring unit is disposed between one of the plungers and a corresponding one of the first pressing block assembly, the second pressing block assemblies, and the third pressing block assemblies of the pressing block mechanism, the load measuring unit is disposed in a carrying area recessed in a center of a fixing member of the first pressing block assembly, the carrying area is used to accommodate the load measuring unit, and the independent one of the pressing rods in the third group independently arranged in the center of the shape of the symbol “ [symbol] ” just correspondingly presses the load measuring unit.

15. The pressing device of claim 13, wherein:
a lower end of each of the pressing rods is provided with a positioning portion, and the positioning portion is formed by cutting off two sides of each of the pressing rods, such that the positioning portion has two sides parallel to each other; and
each of the first pressing block assembly, the second pressing block assemblies, and the third pressing block assemblies is provided with a positioning groove, which is straight long groove-shaped, for the positioning portion at the lower end of each of the pressing rods to be embedded by screwing.

16. The pressing device of claim 15, wherein the positioning grooves are respectively provided for the positioning portions at the lower ends of the pressing rods to be embedded.

17. A pressing device for performing the pressing method as claimed in claim 1.
